(19) United States
(12) Patent Application Publication
(10) Pub. No.: US 2023/0420344 A1
(43) Pub. Date: Dec. 28, 2023

(54) SEMICONDUCTOR APPARATUS

(71) Applicant: NOVATEK MICROELECTRONICS CORP., Hsinchu (TW)

(72) Inventors: Hsueh-Yi Lee, Zhubei (TW); Chun-Hung Chen, Mailiao (TW); Chia-Hsin Tung, Hsinchu (TW); Wen-Pin Tsai, Hsinchu (TW)

(21) Appl. No.: 18/215,339

(22) Filed: Jun. 28, 2023

Related U.S. Application Data
(60) Provisional application No. 63/356,042, filed on Jun. 28, 2022.

(30) Foreign Application Priority Data
Jun. 21, 2023 (CN) 202310742965.7

(51) Int. Cl. H01L 23/498; H01L 25/065; H01L 23/00; H01L 23/31

(52) U.S. Cl. CPC H01L 23/49811; H01L 25/0657; H01L 24/16; H01L 24/08; H01L 24/32; H01L 24/48; H01L 23/3121; H01L 2224/48227; H01L 2224/32146; H01L 2224/16141; H01L 2224/08165; H01L 2225/06541; H01L 2225/06513; H01L 2225/0651; H01L 2924/1437; H01L 2924/1426

(57) ABSTRACT

A semiconductor apparatus is provided. The semiconductor apparatus includes: a first circuit, including a first semiconductor substrate, a first group of circuit components formed on the first semiconductor substrate, and a first group of metal layers, wherein, the first group of circuit components are distributed to at least one circuit block, and traces for each circuit block are formed in at least some of the first group of metal layers; a second circuit, including a second semiconductor substrate, a second group of circuit components formed on the second semiconductor substrate, and a second group of metal layers, wherein, the second group of circuit components are distributed to at least one circuit block, and traces for each circuit block are formed in at least some of the second group of metal layers, and the first circuit and the second circuit being face-to-face stacked and bonded.

### TECHNICAL FIELD

The present disclosure relates to a technical field of semiconductor, and more specifically, to a semiconductor apparatus, for example, an integrated circuit.

### BACKGROUND

In current technical field of semiconductor, integrated circuit design may involve higher-level manufacturing process, so the number of circuit components involved in an integrated circuit chip will be relatively large, making routing very dense and/or complex. Moreover, with the increase in the number of circuit components in the integrated circuit chip, and the increase in complexity and density of routing, the number of metal layers for routing will also increase. The increase in the number of metal layers not only increases costs, but also complicates design and layout.

As an example of an integrated circuit included in an integrated circuit chip, a Display Driver Integrated Circuit (DDIC) may include a plurality of circuit components, for example, a Static Random Access Memory (SRAM) component, an Auto Place & Route (APR) area component, a Gate Driver (GD) component, a Source Driver (SD) component, an Interface (I/O) component, and/or a voltage regulator component, etc. Each of these circuit components may also be composed of one or more circuit elements. A plurality of metal layers are needed for arranging wirings (also referred to as “traces” or “lines”, etc.) for electrical connections between these circuit components and wirings for electrical connections between these circuit components and external components.

However, the number of metal layers in each integrated circuit chip is positively correlated with routing, design and layout complexity, as well as manufacturing costs, etc. Therefore, a solution is needed that is capable of reducing the number of metal layers in each integrated circuit chip, thereby reducing routing, design and layout complexity and manufacturing costs.

### SUMMARY

According to an embodiment of the present disclosure, there is provided a semiconductor apparatus, configured to perform a predetermined function based on a plurality of circuit components, the semiconductor apparatus comprising: a first circuit, including a first semiconductor substrate, a first group of circuit components among the plurality of circuit components formed on the first semiconductor substrate, and a first group of metal layers, wherein, the first group of circuit components are distributed to at least one circuit block, and traces for each circuit block are formed in at least some metal layers of the first group of metal layers; a second circuit, including a second semiconductor substrate, a second group of circuit components among the plurality of circuit components formed on the second semiconductor substrate, and a second group of metal layers, wherein, the second group of circuit components are distributed to at least one circuit block, and traces for each circuit block are formed in at least some metal layers of the second group of metal layers; wherein the first circuit and the second circuit form a stacked structure and have electrical connections, and lower surfaces of the first semiconductor substrate and the second semiconductor substrate respectively serve as an upper surface and a lower surface of the stacked structure.

In the integrated circuit according to the embodiment of the present disclosure, firstly, by distributing the plurality of circuit components into two circuits face-to-face stacked and bonded based on WoW technology, a width of a two-dimensional planar layout sub-region for each circuit component (included in one circuit block) may be increased as compared with the case of integrating the plurality of circuit components into a same circuit, which, thus, may reduce the number of metal layers in each circuit, and further reduce total manufacturing costs and routing, design and layout complexity.

### BRIEF DESCRIPTION OF THE DRAWINGS

The accompanying drawings are used to provide further understanding of the embodiments of the present disclosure, forming a portion of the specification, and are used to explain the present disclosure together with the embodiments of the present disclosure, which do not constitute a limitation on the present disclosure. In the drawings, same reference signs usually represent same/similar components or steps.

FIG. 1 shows a schematic planar view of an exemplary structure of a Display Driver Integrated Circuit (DDIC) as an example of a semiconductor apparatus according to an embodiment of the present disclosure.

FIG. 2 shows a cross-sectional schematic diagram of the exemplary structure in FIG. 1 along A-A′.

FIG. 3 shows a schematic diagram of distributing respective circuit blocks shown in FIG. 1 and FIG. 2 to a first circuit and a second circuit.

FIGS. 4A-4B each show a cross-sectional schematic diagram of the first circuit and the second circuit according to the embodiment of the present disclosure.

FIG. 5 shows a schematic diagram of reducing the number of metal layers in the first circuit and the second circuit according to the embodiment of the present disclosure.

FIG. 6 shows a schematic diagram of distributing two parts of SD components in the display driver integrated circuit into the first circuit and the second circuit respectively according to the embodiment of the present disclosure.

FIG. 7 to FIG. 8 show cross-sectional schematic diagrams of the semiconductor apparatus when the first circuit and the second circuit shown in FIG. 6 each have one part of the (original) SD components.

FIG. 9 shows a schematic diagram of reducing the number of metal layers in the first circuit and the second circuit by sharing a metal layer according to the embodiment of the present disclosure.

FIG. 10 shows a stacked structure based on WoW technology according to the embodiment of the present disclosure, in which there is no shared metal layer in the stacked structure.

FIG. 11 to FIG. 12 each show a stacked structure based on WoW technology according to the embodiment of the present disclosure, in which there is a shared metal layer in the stacked structure.

FIG. 13 to FIG. 14 each show a schematic planar view of an exemplary structure of a display driver integrated circuit including a voltage regulator and not adopting the stacked structure according to the present disclosure.

FIG. 15 shows a schematic planar view of an exemplary structure of a display driver integrated circuit including a voltage regulator and adopting the stacked structure according to the present disclosure.

### DETAILED DESCRIPTION

In order to make objectives, technical details and advantages of the present disclosure apparent, the exemplary embodiments of the present disclosure will be described in details below with reference to the accompanying drawings. It is obvious that the described embodiments are just a part but not all of the embodiments of the present disclosure. It should be understood that the present disclosure is not limited by the exemplary embodiments described here.

In the specification and the drawings, steps and elements that are basically the same or similar are represented by same or similar reference signs, and repeated description of these steps and elements will be omitted. Meanwhile, in the description of the present disclosure, the terms “first”, “second” and the like are only used for distinguishing description, and cannot be understood as indicating or implying relative importance or ranking. Unless explicitly stated, singular expressions may refer to the plural, and plural expressions may also refer to the singular.

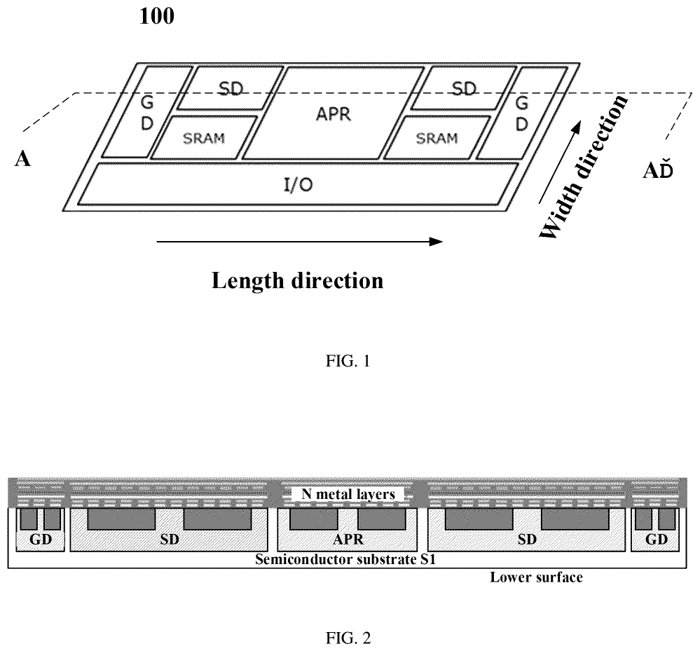

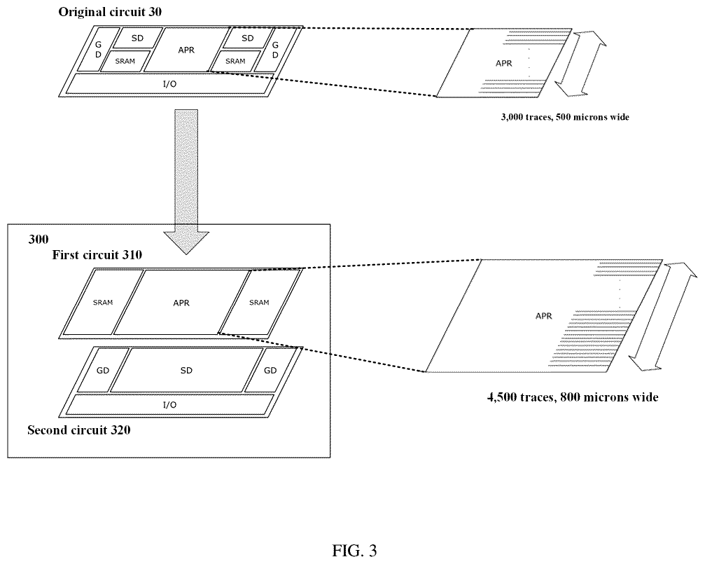

FIG. 1 shows a schematic planar view of an exemplary structure of a Display Driver Integrated Circuit (DDIC) as an example of a semiconductor apparatus according to an embodiment of the present disclosure. FIG. 2 shows a cross-sectional schematic diagram of the exemplary structure in FIG. 1 along A-A′.

The Display Driver Integrated Circuit (DDIC) shown in FIG. 1 is implemented as an integrated circuit chip and performs a display driving function based on a plurality of circuit components. The plurality of circuit components may include analog circuit components (e.g., Gate Drivers (GD), Source drivers (SD), an Interface (I/O)) and digital circuit components (e.g., Static Random Access Memories (SRAMs) and an Auto Place & Route (APR) area). A circuit component herein may refer to a combination of one or more circuit elements.

The plurality of blocks shown in terms of functions in the planar view of FIG. 1 respectively correspond to circuit blocks that will be mentioned later. FIG. 1 schematically shows that the Gate Driver (GD) components, the Source driver (SD) components, and the Static Random Access Memory (SRAM) components are each divided into two parts, the Auto Place & Route (APR) area component is one part (i.e. not divided), and the Interface component is one part (i.e. not divided). However, each type of circuit component may not be divided or may be divided into a plurality of parts of other quantities as needed.

As shown in FIG. 1, all circuit components are included in a same integrated circuit chip 100. As shown in the cross-sectional schematic diagram in FIG. 2, the integrated circuit chip 100 includes a semiconductor substrate 51, all circuit components are formed on the semiconductor substrate 51. In the integrated circuit chip, a group of metal layers (N layers, N being an integer greater than or equal to 2) are arranged over the semiconductor substrate 51 and the circuit components, for arranging traces, that is, for forming electrical connections between circuit components and electrical connections between the circuit components and external components. In addition, for convenience of layout, the circuit components included in the integrated circuit chip 100 may be distributed to at least one circuit block (e.g., whose planar shape is square or rectangle), for example, the SD circuit block on the semiconductor substrate 51 is used for arranging the source driver, and the SRAM circuit block is used for arranging the SRAM, etc. Each circuit block includes at least one circuit component, e.g., may include one or more source drivers, and traces (signal lines and/or power lines) for the circuit block are formed in at least some of the metal layers.

Each block in the planar view shown in FIG. 1 may also be regarded as a view of a projection region of each circuit block on a lower surface of the semiconductor substrate 51, which is also referred to as a planar layout sub-region hereinafter of each circuit block. It may be seen from FIG. 1 that in order to arrange all circuit components within a limited planar layout region, an area, a length, and a width of each circuit block (e.g., an area, a length, and a width of the projection region of the circuit block on the lower surface of the substrate) is relatively small, for example, areas, lengths, and widths of the SD circuit blocks, the SRAM circuit blocks, the GD circuit blocks, etc. are relatively small. Routing for the respective circuit blocks is usually based on region division of circuit blocks. To facilitate routing, the number of traces provided in each metal layer for a circuit block (circuit component(s) thereof) corresponding thereto is positively correlated with the area, length, and/or width of the circuit block, therefore, in a case where the area, length, and/or width of each circuit block is relatively small, the number of traces allowed to be provided in each metal layer for the circuit block is relatively small. It should be noted that with respect to each circuit block, the number of traces provided in a metal layer corresponding thereto is also determined by the width of the metal layer and separation distances between traces in the metal layer, and separation distances between traces determine anti-interference capability between traces. Therefore, in a case where the number of traces provided in each metal layer is constrained by lengths and/or widths of circuit blocks/metal layers, more metal layers are needed for providing traces for each circuit block.

Due to the fact that having more metal layers within each integrated circuit chip means higher routing, design and layout complexity, as well as higher manufacturing costs, a solution is needed to reduce the number of metal layers within each integrated circuit chip.

The embodiment of the present disclosure proposes a solution based on a Wafer-on-Wafer (WoW) technology. The WoW technology includes directly bonding two large-sized wafers (used as semiconductor substrates) that have a plurality of dies (also referred to as semiconductor dies, dies, or IC chips, etc.) formed thereon in a face-to-face manner, and then dicing the two large-sized wafers to obtain a plurality of integrated circuit chips. The dies mentioned here may include various circuit components, and each circuit component may include electronic devices, for example, transistors, capacitors, diodes, storage devices, processors, other devices, and/or integrated circuits, etc.

In a solution based on Wafer-on-Wafer (WoW) technology, a plurality of circuit components or a plurality of circuit blocks to be included in each semiconductor apparatus (e.g., each integrated circuit chip) may be distributed to two integrated circuit chips. For example, the plurality of circuit blocks of the semiconductor apparatus shown in FIG. 1 that performs a display driving function may be distributed to two different integrated circuit chips. Then, the two integrated circuit chips are stacked (e.g., vertically face-to-face stacked) and bonded, so that the two integrated circuit chips could be combined into one semiconductor apparatus, which is then packaged and tested to obtain a final semiconductor chip.

In this way, as compared with arranging these circuit blocks into a single integrated circuit chip, within the semiconductor apparatus including the two integrated circuit chips, respective circuit blocks of the single integrated circuit chip may be rearranged, and an area, a length and/or a length of a planar layout sub-region of at least one circuit block may be increased, so, with respect to these circuit blocks, more traces for these circuit blocks may be provided in each metal layer, which, thus, may reduce the number of metal layers in at least one integrated circuit chip. In addition, in some cases, since the two integrated circuit chips may be vertically face-to-face stacked and bonded, power lines or signal lines may also be shared, which, thus, may further reduce metal layers for arranging power lines or signal lines in at least one integrated circuit chip.

In other words, through WoW technology, respective circuit components (circuit blocks) of in an original single integrated circuit chip may be rearranged into two integrated circuit chips, and the two integrated circuit chips are stacked and bonded, and/or share power lines and/or signal lines, which may reduce routing burden, thus reduce the number of metal layers in at least one integrated circuit chip and reduce overall costs as well as routing, design and layout complexity.

An exemplary structure of a semiconductor apparatus based on WoW technology to reduce the number of metal layers in a single integrated circuit chip according to the embodiment of the present disclosure will be illustrated in detail below in conjunction with FIG. 3 to FIG. 15.

FIG. 3 to FIG. 5 show an exemplary structure of the semiconductor apparatus according to the embodiment of the present disclosure.

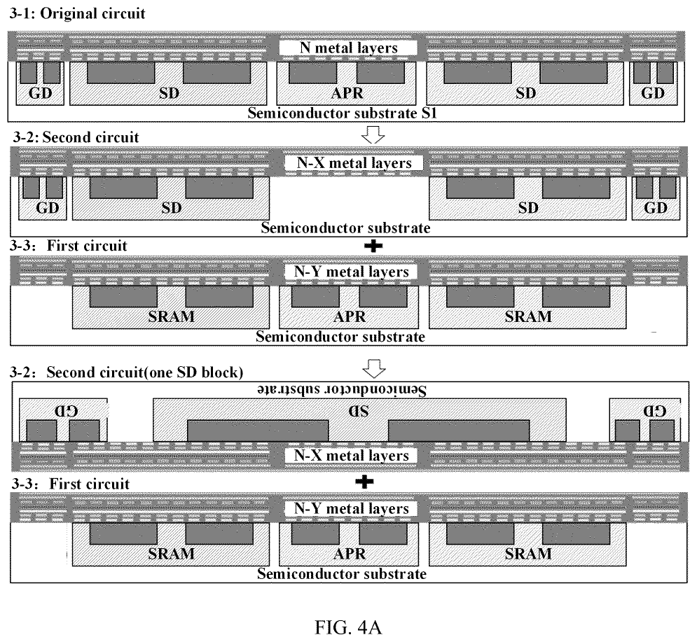

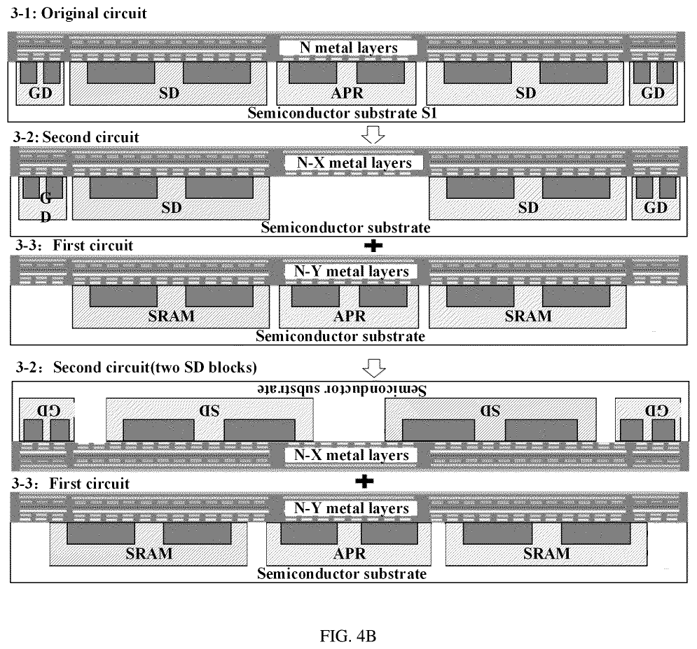

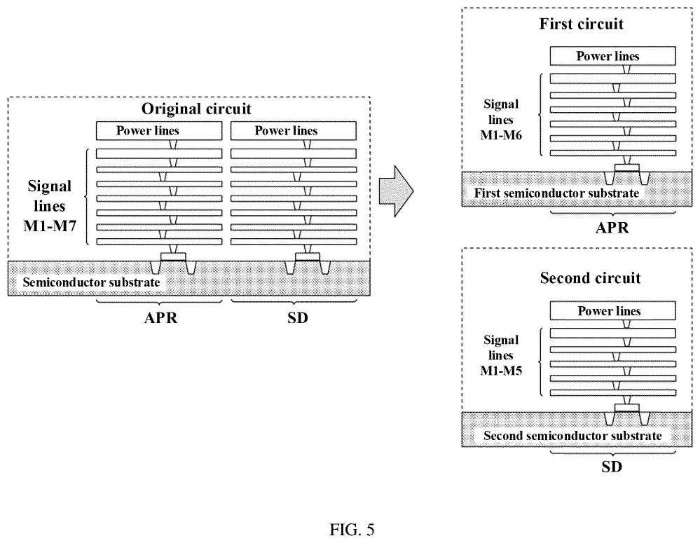

FIG. 3 shows a schematic diagram of distributing respective circuit blocks shown in FIG. 1 to FIG. 2 to a first circuit (the first circuit forming a first integrated circuit chip) and a second circuit (the second circuit forming a second integrated circuit chip). FIGS. 4A-4B each show a cross-sectional schematic diagram of the first circuit and the second circuit. FIG. 5 shows a schematic diagram of reducing the number of metal layers in the first circuit and the second circuit.

For convenience of comparison, a semiconductor apparatus (i.e., an integrated circuit chip formed from an original circuit) that does not adopt the solution based on WoW technology to reduce the number of metal layers is also shown.

It should be noted that in FIG. 3 to FIG. 5, exemplary description is given by taking the semiconductor apparatus as a display driver integrated circuit, however, it should be understood that the semiconductor apparatus may be configured to perform other predetermined functions based on the included plurality of circuit components, and should not be limited to the display driver integrated circuit, but may be other types of integrated circuits, for example, a processing circuit of an image sensor or a memory integrated circuit.

As shown in FIG. 3 and FIGS. 4A-4B, the original circuit 30 includes a plurality of circuit components formed on the semiconductor substrate and N metal layers formed over the semiconductor substrate and the circuit components (N being an integer greater than or equal to 1). These circuit components are distributed to a plurality of circuit blocks, and each circuit block includes at least one circuit component. Traces for each circuit block (e.g., signal lines and/or power lines) are formed in at least some of the metal layers. For example, as shown in FIG. 3 and FIGS. 4A-4B, respective circuit components of the original circuit 30 are distributed to two Gate Driver (GD) circuit blocks, two Source Driver (SD) circuit blocks, one Interface (I/O) circuit block, two Static Random Access Memory (SRAM) circuit blocks, and one Auto Place & Route (APR) area circuit block.

As shown in FIG. 3 and FIGS. 4A-4B, the semiconductor apparatus 300 includes a first circuit 310 and a second circuit 320.

The first circuit 310 includes a first semiconductor substrate, a first group of circuit components formed on the first semiconductor substrate, and a first group of metal layers, wherein, the first group of circuit components are distributed to at least one circuit block, and traces for each circuit block are formed in at least some metal layers of the first group of metal layers.

Similarly, the second circuit 320 includes a second semiconductor substrate, a second group of circuit components formed on the second semiconductor substrate, and a second group of metal layers, wherein, the second group of circuit components are distributed to at least one circuit block, and traces for each circuit block are formed in at least some metal layers of the second group of metal layers.

For example, as shown in FIG. 3 and FIGS. 4A-4B, taking the semiconductor apparatus 300 being a display driver integrated circuit as example, the first group of circuit components included in the first circuit 310 may include Static Random Access Memories (SRAMs) and an Auto Place & Route (APR) area, and the second group of circuit components included in the second circuit 320 may include Gate Drivers (GDs), Source Drivers (SDs), and an Interface (I/O). Correspondingly, in order to arrange these circuit components, the first circuit may include two Static Random Access Memory (SRAM) circuit blocks and one Auto Place & Route (APR) area circuit block, while the second circuit may include two Gate Driver (GD) circuit blocks, one Source Driver (SD) circuit blocks (as shown in FIGS. 3 and 4A) or two SD circuit blocks (as shown in FIG. 4B), and one Interface (I/O) circuit block. It should be noted that the positions and sizes of each circuit block shown in the figures are exemplary, and the positions and sizes of the circuit blocks could be changed according to actual needs.

The first circuit 310 and the second circuit 320 form a stacked structure and have electrical connections (e.g., signal and/or power connections) therebetween. A lower surface of the first semiconductor substrate and a lower surface of the second semiconductor substrate respectively serve as an upper surface and a lower surface of the stacked structure, that is to say, the first circuit 310 and the second circuit 320 are face-to-face stacked and bonded.

For example, the semiconductor substrates in the first circuit and the second circuit are fabricated based on WOW technology. For example, the semiconductor substrates of two circuits are supplied by different wafers. For example, a plurality of first circuits and a plurality of second circuits are respectively formed on two large-sized circular wafers, and each pair of a first circuit and a second circuit corresponding to each other in the two wafers are face-to-face aligned and bonded, and diced into a single semiconductor apparatus, for example, an Integrated Circuit (IC) chip.

In this way, with respect to each of the first circuit 310 and the second circuit 320, an area of the planar layout region thereof is the same as that of the original circuit, so an area (or a length or a width) of a planar layout sub-region distributed to each circuit block increases, so that the maximum number of traces for each circuit block that may be accommodated in one metal layer of the first circuit and/or the second circuit becomes larger, and the number of metal layers in each of the first circuit and the second circuit may be reduced. For example, as shown in FIG. 3, a width of the planar layout sub-region distributed to the APR circuit block in the original circuit may be 500 microns, and approximately 3,000 traces for the APR circuit block may be arranged in one metal layer of the original circuit; meanwhile, the width of the planar layout sub-region distributed to the APR circuit block in the first circuit may be 800 microns wide, so that approximately 4,500 traces for the APR circuit block may be arranged in one metal layer of the first circuit, which, thus, may reduce the number of metal layers in the first circuit. In one embodiment, the APR circuit block may be an example of a digital control logic circuit block.

In one embodiment, a planar shape of the semiconductor apparatus (e.g., the Display Driver Integrated Circuit (DDIC)) usually has a longer length but a shorter width. Therefore, if a width of a planar layout sub-region allocated to each circuit block is larger, circuit components (each including one or more circuit elements) inside the circuit block may be repositioned and there is more room for routing. Therefore, routing may be simplified.

FIGS. 4A-4B illustrate cross-sectional schematic diagrams of respective circuits. Reference sign 3-1 indicates a cross-sectional schematic diagram of the original circuit. Reference sign 3-2 indicates a cross-sectional schematic diagram of the second circuit. Reference sign 3-3 indicates a cross-sectional schematic diagram of the first circuit. It may be seen from the diagrams that the number of metal layers in the original circuit is N, the number of metal layers in the second circuit is reduced from N layers to N—X layers as compared with the original circuit, where, N≥2 and X≥1, and the number of metal layers in the first circuit is reduced from N layers to N—Y layers as compared with the original circuit, where, N≥2 and Y≥1.

FIG. 5 further shows a schematic diagram of reducing the number of metal layers in the first circuit and the second circuit.

As shown in FIG. 5, the original circuit includes 7 metal layers for forming signal lines and includes 1 metal layer for forming power lines. After dividing the original circuit into a first circuit and a second circuit, widened widths and/or longer lengths of planar layout sub-regions of respective circuit blocks result in a greater number of traces per metal layer for the circuit blocks. So, the number of metal layers in the first circuit may be reduced by, for example, 1 layer (i.e. X=1), that is, 6 metal layers are used for forming signal lines, and the number of metal layers in the second circuit may be reduced by, for example, 2 layers (i.e. Y=2), that is, 5 metal layers are used for forming signal lines. Therefore, as compared with the integrated circuit chip formed by the original circuit, the number of metal layers of the first integrated circuit chip formed by the first circuit is reduced, and the number of metal layers of the second integrated circuit chip formed by the second circuit is also reduced, thereby reducing routing, design and layout complexity within each integrated circuit chip and reducing circuit design and manufacturing costs.

FIG. 5 exemplarily shows that these signal lines/power lines are used for the APR circuit block and the SD circuit block. However, it should be understood that traces used for all circuit blocks in the original circuit, the first circuit, and the second circuit are all formed in the metal layers shown, while traces used for circuit components of different circuit blocks may be formed in different combinations of metal layers. For example, in a same circuit, traces used for the first circuit component are formed in a first metal layer and a second metal layer, while traces used for the second circuit component are formed in the second metal layer to a fifth metal layer. In a same circuit, if traces used for circuit components of different circuit blocks are formed in a same metal layer(s), these traces for the circuit components of different circuit blocks are separated in the same metal layer(s). In addition, there are also vertical interconnecting structures (e.g., via holes) between metal layers, and there are also electrical connecting structures or vertical interconnecting structures (e.g., via holes) between the lowest metal layer and circuit components on the semiconductor substrate, so that traces in respective metal layers are capable of supplying signals and power to the circuit components. In addition, each circuit block (including one or more circuit components) on the semiconductor substrate is not explicitly shown in the figure, but it should be understood that corresponding circuit components are formed on the semiconductor substrate.

That is to say, the number of metal layers in the original circuit, the first circuit, or the second circuit as mentioned in the context of the present disclosure refers to the maximum number of metal layers for forming the traces for respective circuit blocks in respective circuits. For example, in the first circuit, the signal lines for APR circuit block need to be formed in 6 metal layers, meanwhile, signal lines for the SRAM circuit block may only need to be formed in 4 metal layers. In this case, it is still considered that the number of metal layers for forming signal lines in the first circuit, including the APR circuit block and the SRAM circuit block, is 6.

The solution has been described above in conjunction with FIG. 3 to FIG. 5 that a single integrated circuit chip formed by the original circuit is divided into two integrated circuit chips that are face-to-face stacked and bonded, which may reduce the number of metal layers in each integrated circuit chip, and further reduce the total manufacturing costs, and routing, design and layout complexity. In the solution, reduction of metal layers within each integrated circuit chip has advantages such as layout space optimization, manufacturing process simplification, and cost reduction.

In some embodiments of the present disclosure, circuit components distributed to the first circuit and the second circuit may be determined in different ways.

For example, the first circuit may only include digital circuit components, and the second circuit may only include analog circuit components. Or, comparing components in the first circuit and in the second circuit, the first circuit may include more digital circuit components and fewer analog circuit components, and the second circuit may include more analog circuit components and fewer digital circuit components.

For example, digital circuit components mainly include low voltage devices. For example, SRAM and APR components in the display driver integrated circuit, as digital circuit components, need to deal with functions such as high resolution, high frame rate, and image data processing, etc., so it is necessary to improve operation speed and clock rate. In addition, in order to improve speed of components and avoid high power consumption, a higher-level of manufacturing process is required to reduce operating voltages in terms of SRAM and APR components. The higher-level manufacturing process have characteristics of high density, small chip size, and high cost. Analog circuit components may include medium voltage devices or high voltage devices, for example, GD components, SD components, and I/O interface components in the display driver integrated circuit. A process for a longer channel length and a higher withstand voltage is used for the analog circuit components, considering the output voltage specification of a product. A medium or high voltage device requires no process scaling, costs less, with bigger area, has the operating voltage and frequency which do not increase continuously, or is sufficient to meet specification requirements.

In other words, digital circuit components may require a manufacturing process different from that for analog circuit components. In one embodiment, digital circuit components may be fabricated through a higher-level manufacturing process, while analog circuit components may be fabricated through a low-end manufacturing process. Therefore, the first circuit may be mainly or entirely provided with digital circuit components, and the second circuit may be mainly or entirely provided with analog circuit components.

Optionally, the first circuit and the second circuit may be fabricated by different manufacturing processes (e.g., manufacturing processes of different generations). Or, the first circuit and the second circuit may be fabricated by using a same manufacturing process (e.g., manufacturing processes of a same generation).

Optionally, in other embodiments, circuit components of a same type may also be arranged in different circuits in a face-to-face manner, that is, the first circuit includes a first circuit block, the second circuit includes a second circuit block, and the first circuit block includes the circuit component(s) of a same type as the circuit component(s) included in the second circuit block. When the first circuit and the second circuit form the stacked structure, the first circuit block and the second circuit block are arranged opposite to each other, or the first circuit block is arranged opposite to another circuit block in the second circuit except for the second circuit block.

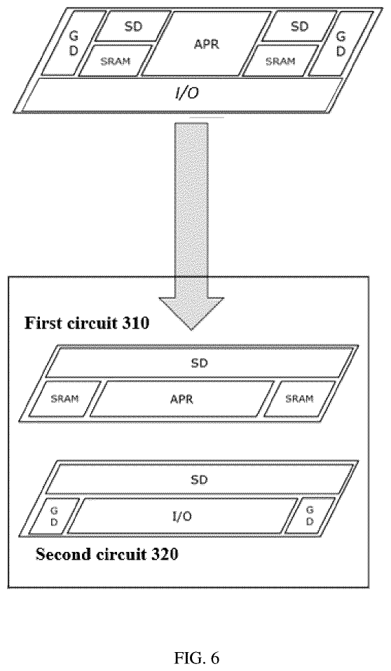

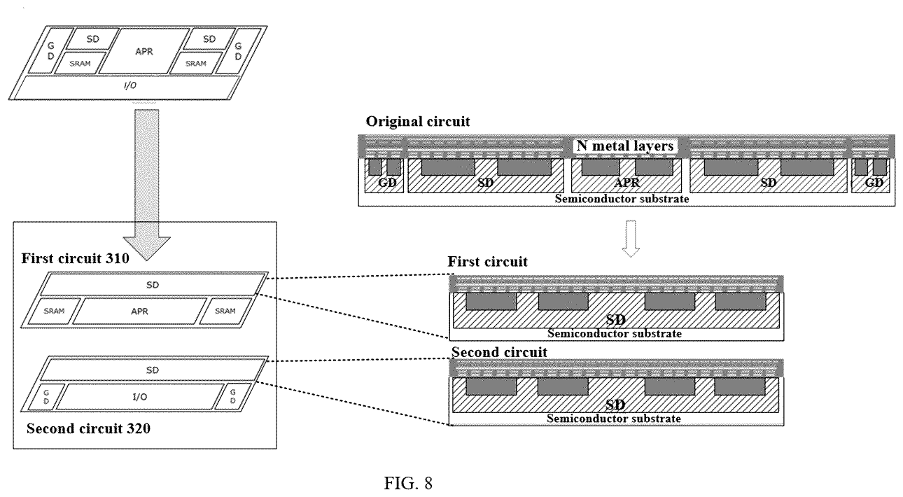

FIG. 6 shows a schematic diagram of dividing SD components in the display driver integrated circuit into two parts which are respectively distributed to the first circuit and the second circuit. As shown in FIG. 6, the first circuit may further include one part of the SD components (the SD components in the original circuit) (also referred to as a first SD component), in addition to the SRAM components and the APR component, and the second circuit may further include another one part of the SD components (also referred to as a second SD component), in addition to the GD components and the I/O component. For example, the first SD component in the first circuit includes some level shifters, while the second SD component in the second circuit includes other level shifters. It should be noted that although FIG. 6 and subsequent FIG. 8 show that the original circuit includes two SD blocks (for two SD components), the original circuit may also include one SD block, and the SD component set in the SD block is divided into two parts to be placed in the first circuit and the second circuit respectively. The number of various circuit components (and corresponding circuit blocks) included in the circuits is not limited in this application.

That is to say, if necessary, any type of circuit component(s) in the original circuit may be divided into at least two parts which are respectively distributed to the first circuit and the second circuit. Alternatively, multiple circuit components of the same type could be arranged into a same circuit block of a same circuit.

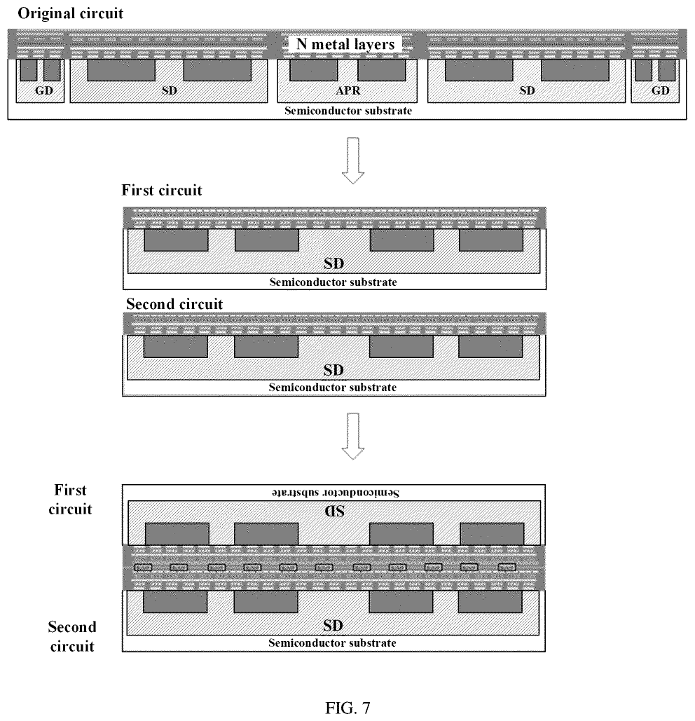

FIG. 7 to FIG. 8 show cross-sectional schematic diagrams of the semiconductor apparatus when both the first circuit and the second circuit shown in FIG. 6 each have a part of the (original) SD components. In order to highlight the divided SD components, only cross-sectional schematic diagrams related to the SD components are shown for the first circuit and the second circuit. The sizes shown in the figure are also exemplary. The first circuit and the second circuit may have the same planar size as the original circuit.

It could be seen that in FIG. 7 and FIG. 8, the first circuit and the second circuit each include an SD circuit block, wherein, each SD circuit block includes a part of the SD components. Since the two SD circuit blocks need to electrically connect to each other, when the first circuit and the second circuit are face-to-face stacked and boned, a bump may be used to connect the two SD circuit blocks of the two circuits.

In other embodiments, the SRAM circuit components (in the original circuit) may also be divided into two parts. One part of the SRAM circuit components (e.g., one SRAM circuit component) is arranged in the first circuit as a first SRAM component, while the other part thereof (e.g., another one SRAM circuit component) is arranged in the second circuit as a second SRAM component. Since the SRAM circuit components needs to be connected with the APR circuit component, a circuit block including the second SRAM component in the second circuit may be arranged opposite to a circuit block including the APR circuit component in the first circuit when the first circuit and the second circuit are face-to-face stacked and bonded, to shorten a distance between the second SRAM component in the second circuit and the APR circuit component in the first circuit after the first circuit and the second circuit are face-to-face stacked and bonded, so as to reduce complex routing and speed up the operation of the APR circuit component.

Optionally, planar layout sub-regions for respective circuit blocks in the planar layout region of the first circuit or the second circuit (i.e., projection regions of the circuit blocks on the lower surface of the semiconductor substrate of the first circuit or the second circuit) are rectangle or square in shape. Since a planar layout sub-region for each circuit block may be larger than that of the circuit block in the original circuit, shapes of planar layout sub-regions of certain circuit blocks in the first circuit and the second circuit (i.e. a projection region on the lower surface of the semiconductor substrate of the first circuit or the second circuit) each may be squarer than planar layout sub-regions of corresponding circuit blocks in the original circuit.

In one embodiment, one or more sides of the projection region of each circuit block on a lower surface of its corresponding semiconductor substrate (briefly referred to as a projection region corresponding to the circuit block or a planar layout sub-region of the circuit block) are adjacent to or aligned with one or more sides of the lower surface of the corresponding semiconductor substrate. For example, as shown in FIG. 3, two sides in a length direction of the projection region corresponding to the APR circuit block (an APR upper side and an APR lower side as shown in the diagram) are adjacent and parallel to two sides in the length direction of the lower surface of the semiconductor substrate of the first circuit, and two sides in a width direction (an APR left side and an APR right side as shown in the diagram) are aligned with two sides in the width direction of the lower surface of the semiconductor substrate of the first circuit.

In one embodiment, at least two sides of the projection region of each circuit block (e.g., an APR circuit block or an SRAM circuit block) in one or more circuit blocks on the lower surface of its corresponding semiconductor substrate are adjacent to or aligned with sides of the lower surface of the corresponding semiconductor substrate. For example, as shown in FIG. 3, two sides in the length direction of the projection region corresponding to the APR circuit block (e.g., an APR upper side and an APR lower side as shown in the diagram) are adjacent and parallel to two sides in the length direction of the lower surface of the semiconductor substrate of the first circuit (e.g., the upper side and the lower side as shown in the diagram). Two sides in the length direction and width direction of the projection region corresponding to the right-side GD circuit block (e.g., a GD upper side and a GD right side as shown in the diagram) are adjacent and parallel to two sides of the lower surface of the semiconductor substrate of the second circuit (e.g., the upper side and the right side as shown in the diagram), and so on.

In one embodiment, projection regions of two or more different circuit blocks in a same circuit on the lower surface of the semiconductor substrate of the same circuit have a same width. For example, as shown in FIG. 3, the width of the projection region corresponding to the APR circuit block in the first circuit may be substantially equal to the width of the projection region corresponding to the SRAM circuit block (or even equal to the width of the planar layout region of the first circuit (or the width of the lower surface of the semiconductor substrate of the first circuit)). The width of the projection region corresponding to the SD circuit block in the second circuit may be substantially equal to the width of the projection region corresponding to the GD circuit block.

In one embodiment, with respect to each circuit block, the projection region of the circuit block on the lower surface of its corresponding semiconductor substrate has a first side longer than a second side, in which the first side is a side adjacent or parallel to the projection region of another circuit block in the same circuit on the lower surface of the corresponding semiconductor substrate, and the second side is another side of the projection region of the circuit block on the lower surface of the corresponding semiconductor substrate, so as to facilitate arranging traces for electrical connection between adjacent circuit blocks. For example, the length of the side of the projection region corresponding to the APR circuit block that is adjacent or parallel to the projection region corresponding to the SRAM circuit block (i.e., the length of the side in the width direction of the projection region corresponding to the APR circuit block) may be much longer than the length of the side that is not adjacent or parallel to the projection region corresponding to the SRAM circuit block (i.e., the length of the side in the length direction of the projection region corresponding to the APR circuit block).

Of course, projection regions (planar layout sub-regions) of respective circuit blocks on the lower surface of the semiconductor substrate have a rectangle or square shape, so position and size of the projection region of each circuit block may be appropriately arranged within the planar layout region for the semiconductor apparatus according to actual situations.

According to other implementations of the present disclosure, the number of metal layers in at least one of the first circuit and the second circuit may be further reduced by sharing one or more metal layers (hereinafter referred to as shared metal layers) between the first circuit and the second circuit. For example, after the first circuit and the second circuit form the stacked structure (face-to-face stacked and bonded), the first circuit block included in the first circuit will be arranged opposite to the second circuit block included in the second circuit, that is, facing each other. There are metal layers sandwiched between the circuit components in the first circuit block and the circuit components in the second circuit block (including metal layers from the first group of metal layers in the first circuit and the second group of metal layers in the second circuit), and one or more of these metal layers may be shared by the first circuit and the second circuit, for example, shared by the first circuit block and the second circuit block. For example, one or more metal layers having similar or identical properties or functions, i.e. one or more metal layers provided with one or more signal lines or power lines having similar or identical properties or functions, may be shared by the first circuit and the second circuit.

For example, the shared metal layer may include a metal layer for arranging power lines and/or signal lines. For example, the first circuit block and the second circuit block need to acquire same power, so a metal layer arranged with power lines may be shared. For example, the circuit components in the first circuit block may acquire power from power lines in a metal layer arranged with the power lines for the circuit components in the second circuit block. In addition, the circuit components in the first circuit block and the second circuit block may send or receive signals through same signal lines, so at least one metal layer for arranging the signal lines may be shared, especially in a case where the first circuit block and the second circuit block include different parts of a certain type of circuit components.

For example, in a case where the SD components in the display driver integrated circuit are divided into two parts which are respectively arranged in the first circuit and the second circuit as shown in FIG. 6 to FIG. 8, the first circuit block in the first circuit includes a part of the SD components as a first SD component, and the second circuit block in the second circuit includes another part of the SD components as a second SD component, and the first circuit block and the second circuit block are arranged face-to-face. Since the first SD component and the second SD component in the two circuit blocks perform a same function, there is no need to provide the metal layer for arranging these signal lines in one of the first circuit and the second circuit (if the metal layer is also not required for arranging other signal lines for circuit components in other circuit blocks in the one of the first circuit and the second circuit), that is, one or more signal lines (power lines) having similar properties or characteristics may be shared between the first circuit and the second circuit for use, to reduce the number of metal layers.

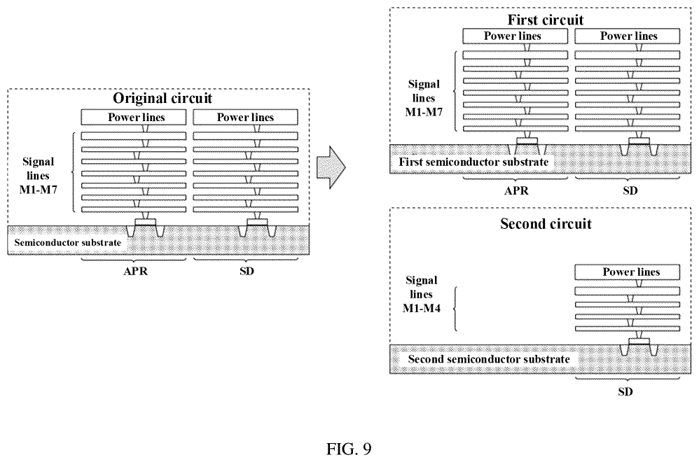

FIG. 9 further shows a schematic diagram of reducing the number of metal layers in the first circuit and the second circuit by sharing metal layers. For illustration purposes, FIG. 9 only shows the APR component and SD components as well as relevant metal layers thereof.

As shown in FIG. 9, the first circuit includes an APR component and a first SD component; and the second circuit includes a second SD component.

By making the first SD component in the first circuit and the second SD component in the second circuit share one or more signal lines (or power lines), i.e. share one or more metal layers for arranging these signal lines (or power lines), the number of metal layers in at least one of the first circuit and the second circuit may be reduced.

For example, some metal layers for arranging signal lines in the first circuit may be shared with the second SD component in the second circuit, and/or some metal layers for arranging signal lines in the second circuit may be shared with the first SD component in the first circuit. Therefore, as shown in FIG. 9, the number of metal layers for arranging the signal lines in the second circuit is reduced from 7 to 4. Since the first circuit also includes other circuit components that need a plurality of metal layers (e.g., 7 layers), for example, the APR component, the number of metal layers in the first circuit is not reduced (e.g., still 7 layers), so as to meet requirements of other circuit components. Of course, in other embodiments, some metal layers for arranging signal lines in the second circuit may also be shared with other components in the first circuit except for the first SD component, or the metal layers for arranging power lines in the second circuit may be shared with the first circuit, so the number of metal layers in the first circuit may also be reduced.

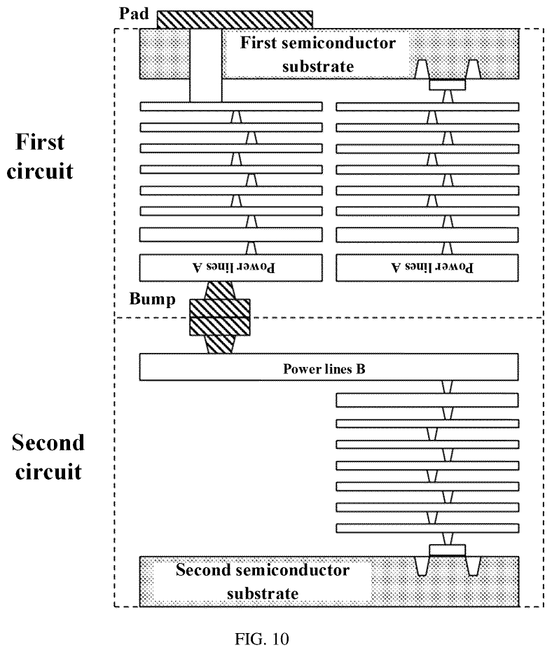

Hereinafter, a semiconductor apparatus including a stacked structure based on WoW technology will be described in conjunction with FIG. 10 to FIG. 12, to more fully illustrate the semiconductor apparatus as described above with reference to FIG. 3 to FIG. 9.

FIG. 10 shows a stacked structure based on WoW technology, in which there is no shared metal layers in the stacked structure.

As shown in FIG. 10, the first circuit and the second circuit each include seven metal layers for arranging signal lines and one metal layer for arranging power lines. A topmost pad of the first circuit is a pad for bonding the first circuit to other circuits. The first circuit and the second circuit are bonded through a bump. For example, the first circuit uses power line A, the second circuit uses power line B, and power lines A and B are connected through the bump. There are also via holes between metal layers, and there are also electrical connecting mechanisms or via holes between a lowest metal layer and circuit components on the semiconductor substrate, so that traces in respective metal layers are capable of supplying signals and power to the circuit components.

It should be noted that in FIG. 10, since current flowing on the power line is larger than current flowing on the signal lines, it is schematically shown that the power line A or B is wider than each signal line.

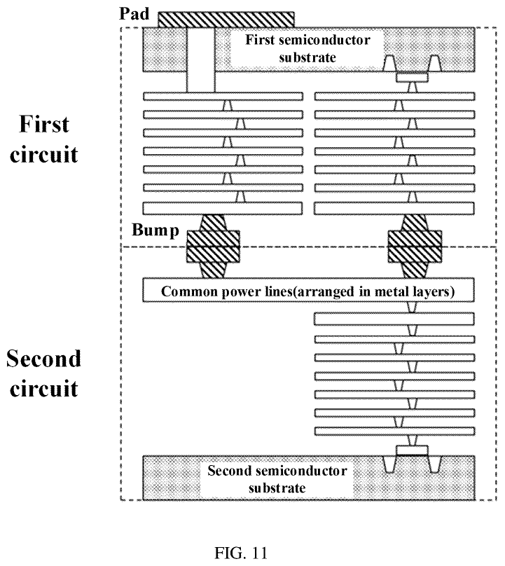

FIG. 11 shows a stacked structure based on WoW technology, wherein, as compared with FIG. 10, no metal layer for arranging the power line in the first circuit, because the metal layer for arranging the power line in the second circuit may be shared with the first circuit (e.g., the first circuit block), that is, the circuit component in the first circuit may acquire power from the power line (shared power line) in the second circuit through an electrical connecting structure (e.g., a bump) between the first circuit and the second circuit. Therefore, the number of metal layers in the first circuit decreases, and the number of metal layers in the second circuit may be changed (e.g., the metal layer for arranging signal lines in the first circuit may be shared with the second circuit) or unchanged.

Of course, the metal layer for arranging the power line in the first circuit may also be shared with the second circuit to reduce the number of metal layers in the second circuit.

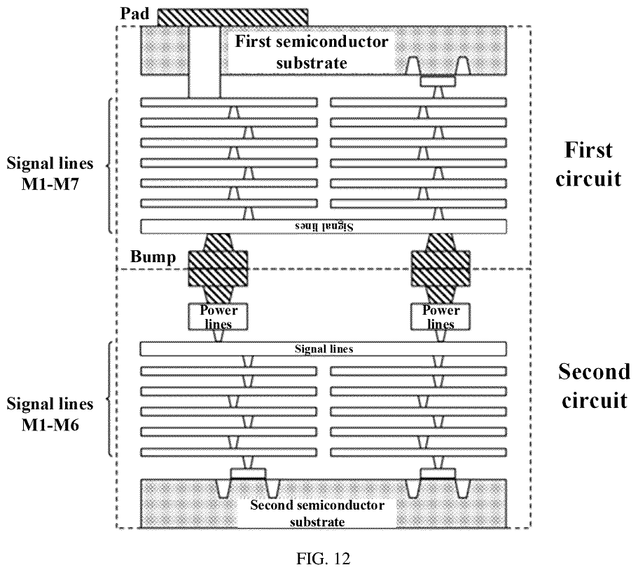

FIG. 12 shows a stacked structure based on WoW technology, in which signal lines in the first circuit are arranged in seven different metal layers, while signal lines in the second circuit are arranged in six different metal layers and power lines are arranged in one metal layer. It may be seen from FIG. 12 that there is no metal layer for arranging the power line in the first circuit, and at least one metal layer for arranging the signal lines is reduced in the second circuit, because the first circuit and the second circuit may share the power line and/or the signal lines with each other. The circuit components in the first circuit may acquire power from the power line (the shared power line) in the second circuit, or acquire signals from the signal lines (the shared signal lines) in the second circuit or send signals through the signal lines (the shared signal lines) to circuit components in the second circuit, via an electrical connecting structure (e.g., a bump) between the first circuit and the second circuit. In addition, even if when sharing, the signal lines in the second circuit are shared with the first circuit, since it is necessary to satisfy the requirements of other circuit components in the first circuit for metal layers, the number of metal layers for arranging signal lines in the first circuit may not decrease, as shown in the diagram, there are still seven metal layers for arranging signal lines in the first circuit. The number of metal layers in the second circuit may be reduced, for example, with respect to the signal lines in the six metal layers in the second circuit as shown in the diagram, the signal lines in the first circuit may also be shared with the second circuit considering similar properties or functions, that is, the metal layer for arranging the signal lines in the first circuit may be shared with the second circuit, the circuit components in the second circuit may acquire signals from signal lines (shared signal lines) in the first circuit and send signals through the signal lines (shared signal lines) to the circuit components in the first circuit, via an electrical connecting structure (e.g., a bump) between the first circuit and the second circuit.

For example, signal lines in the first circuit that are arranged in one or more metal layers and are used for supplying signals to the first SD component in the first SD circuit block may be shared with the second circuit (e.g., the second SD component in the second SD circuit block), that is, the second SD component in the SD circuit block of the second circuit may acquire signals from the signal lines in the one or more metal layers of the first circuit used for arranging traces for the first SD component of the first SD circuit block. For example, the shared signal lines may be configured to transmit gamma voltages.

Of course, similarly, signal lines in the second circuit that are arranged in one or more metal layers and are used for supplying signals to the second SD component in the second SD circuit block may also be shared with the first circuit (e.g., the first SD component in the first SD circuit block) to reduce the number of metal layers in the first circuit.

That is to say, power lines and/or signal lines in one or more metal layers included in one of the first circuit and the second circuit may be shared with the other one of the first circuit and the second circuit, so as to reduce the number of metal layers included in at least one of the first circuit and the second circuit. By sharing metal layers, routing can be simplified or optimized to avoid inefficient routing.

In addition, in other implementations, since one or more of respective circuit components need to be powered, for example, the APR component in the display driver integrated circuit, i.e. the circuit component to be powered is included in the integrated circuit, the semiconductor apparatus (e.g., the semiconductor apparatus 300 as described above, etc.) may further include a voltage regulator.

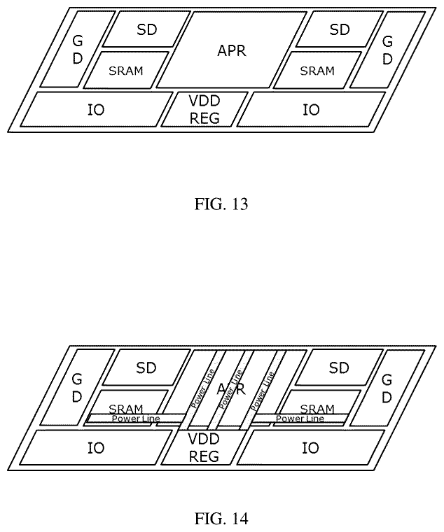

FIG. 13 to FIG. 14 each show a schematic planar view of an exemplary structure of a display driver integrated circuit including a voltage regulator and not adopting the stacked structure according to the present disclosure. The voltage regulator VDD REG may be used for supplying power to an APR component and/or an SRAM component. A circuit block that includes the voltage regulator VDD REG is referred to as a voltage regulator circuit block (i.e., a power supplying circuit block), and a circuit block that includes the APR component and/or the SRAM component is referred to as an APR circuit block and/or an SRAM circuit block (i.e., a circuit block to be powered).

Due to high power consumption of the APR component and/or the SRAM component, in current technologies, it is necessary to connect the voltage regulator VDD REG with the APR component and/or the SRAM component through an power line(s). For example, power supplying paths from the voltage regulator VDD REG to the APR component and/or to the SRAM component are etched in a semiconductor substrate, so as to form the internal power line(s) (not arranging in the metal layers), or the power line(s) are arranged in the metal layers. FIG. 14 further shows the power lines for transmitting power output by the voltage regulator circuit block on the basis of FIG. 13. As shown in FIG. 14, the power lines for transmitting power output from the voltage regulator circuit block to, for example, the APR circuit block and/or the SRAM circuit block, extends to the APR circuit block and/or the SRAM circuit block. The power lines shown in FIG. 14 may pass through the entire APR circuit block and/or the entire SRAM circuit block, and the power lines may be wide and of high density.

Therefore, in the structure shown in FIG. 13 to FIG. 14, there is a need for longer power lines with higher density, which is not favorable for layout. In this regard, improvement may be made by adopting the stacked structure as described above.

For example, in the context, assuming that the first circuit includes a circuit component to be powered (e.g., the APR component and/or the SRAM component), then one or more voltage regulators are arranged in the second circuit to supply power to the circuit component to be powered in the first circuit. Of course, a circuit component to be powered may also be included in the second circuit, so that one or more voltage regulators may be arranged in the first circuit to supply power to the circuit component to be powered in the second circuit.

For example, the one or more voltage regulators are arranged in one or more power supplying circuit blocks of the second circuit, and the one or more power supplying circuit blocks and the circuit blocks to be powered including the circuit components to be powered in the first circuit are arranged opposite to each other (i.e., arranged face-to-face).

Optionally, a projection region of the one or more power supplying circuit blocks on the lower surface of the first semiconductor substrate in the first circuit overlaps with a middle region of a projection region of the circuit blocks to be powered on the lower surface of the first semiconductor substrate.

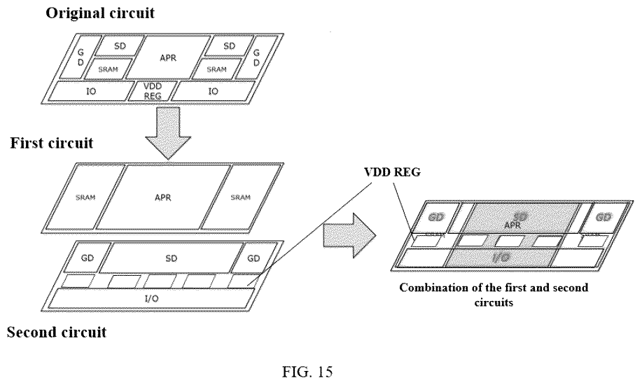

FIG. 15 shows a schematic planar view of an exemplary structure of a display driver integrated circuit including a voltage regulator and adopting the stacked structure in which a plurality of voltage regulators VDD REG may be used for supplying power to the APR component and/or the SRAM component.

As shown in FIG. 15, the circuit blocks in the first circuit and the second circuit may be rearranged: for example, a plurality of voltage regulator circuit blocks may be distributed within the second circuit and in the middle of the planar layout region of the second circuit (corresponding to the middle region of the planar layout region of the first circuit), instead of being distributed next to the APR circuit block in the first circuit. After the first circuit and the second circuit are face-to-face stacked and bonded, the voltage regulator circuit blocks and the APR and SRAM circuit blocks are arranged oppositely, and there are metal layers capable of transmitting power generated by the voltage regulators sandwiched between the voltage regulator circuit blocks and the APR and SRAM circuit blocks, so that the circuit components in the APR and SRAM circuit blocks in the first circuit may acquire power from the voltage regulators in the second circuit, which, as compared with the solution based on power lines shown in FIG. 14, may simplify routing in the first circuit. That is, power output by the plurality of voltage regulators in the plurality of voltage regulator circuit blocks in the second circuit is used by the circuit components in the APR circuit block and the SRAM circuit block in the first circuit, for example, the power may be transmitted through power lines in a certain metal layer(s) in the second circuit, an electrical connecting structures (e.g., bumps) between the first circuit and the second circuit, and vertical interconnecting structures (e.g., via holes) between respective metal layers in the first circuit and the second circuit, and optionally power lines provided in metal layers in the first circuit, from the voltage regulators in the second circuit to the APR and SRAM circuit components in the first circuit. For example, in the embodiment of sharing metal layers as mentioned above, the metal layers for arranging power lines for APR and SRAM circuit blocks may not be provided in the first circuit, so that the number of metal layers in the first circuit could be reduced (if these metal layers do not need to be provided with signal lines or power lines for other circuit blocks).

In the combination of the first circuit and the second circuit, the voltage regulator circuit blocks may be arranged to correspond to the middle region of the planar layout sub-region of the APR circuit block and correspond to the middle region of the planar layout sub-region of the SRAM circuit block, that is, a projection region of the voltage regulator circuit blocks on the lower surface of the first (or second) semiconductor substrate in the first (or second) circuit overlaps with the middle region of the projection region of the APR circuit block and the SRAM circuit block on the lower surface of the first (or second) semiconductor substrate, in order to save power lines.

Therefore, routing efficiency of power lines is higher, which avoids high-density power lines and reduces use of power lines. In summary, respective circuit blocks (especially the circuit blocks to be powered) may be repositioned and reorganized according to the characteristics of WoW technology to prevent invalid power lines. Since the voltage regulator (e.g., a linear voltage regulator) generally has low costs and small volume, arrangement of the plurality of voltage regulators will not introduce excessive costs and volume consumption.

Therefore, in the integrated circuit according to the embodiment of the present disclosure, firstly, by distributing the plurality of circuit components into two circuits face-to-face stacked and bonded based on WoW technology, a width of a two-dimensional planar layout sub-region for each circuit component (each circuit block) may be increased as compared with the case of integrating the plurality of circuit components into a same one circuit, which, thus, may reduce the number of metal layers in each circuit, and further reduce total manufacturing costs and routing, design and layout complexity. In addition, in a case where the first circuit of the two circuits includes power supplying components, the power supplying circuit blocks may be distributed in the middle of the projection region of the circuit blocks to be powered of the second circuit of the two circuits on the lower surface of the semiconductor substrate of the first circuit, so that the power supplying circuit blocks may overlap with the circuit blocks to be powered after the two circuits are face-to-face stacked and bonded, which, thus, may simplify routing, save power lines, so that the routing efficiency of power lines could be improved, high-density power lines could be avoided, and the use of power lines could be reduced.

Although some embodiments of the present disclosure and advantages thereof have been described in detail, it should be understood that various changes, substitutions, and modifications may be made herein without departing from the spirit and scope of the present disclosure as defined by the appended claims. For example, those ordinarily skilled in the art will easily understand that many of the components, functions, processes, and materials as described herein may be changed while still within the scope of the present disclosure. In addition, the scope of the present disclosure is not intended to be limited to specific embodiments of processes, machines, fabrication, material compositions, tools, methods, and steps as described in the specification. According to the present disclosure, those skilled in the art will easily understand from the disclosure of the present disclosure that existing or later developed processes, machines, fabrication, material compositions, tools, methods or steps that perform substantially the same functions or implement substantially the same results as the corresponding embodiments described herein may be utilized. Therefore, the appended claims aim to include these processes, machines, fabrication, material compositions, tools, methods, or steps within the scope thereof.

1. A semiconductor apparatus, configured to perform a predetermined function based on a plurality of circuit components, the semiconductor apparatus comprising:
a first circuit, including a first semiconductor substrate, a first group of circuit components among the plurality of circuit components formed on the first semiconductor substrate, and a first group of metal layers, wherein, the first group of circuit components are distributed to at least one circuit block, and traces for each circuit block are formed in at least some metal layers of the first group of metal layers;
a second circuit, including a second semiconductor substrate, a second group of circuit components among the plurality of circuit components formed on the second semiconductor substrate, and a second group of metal layers, wherein, the second group of circuit components are distributed to at least one circuit block, and traces for each circuit block are formed in at least some metal layers of the second group of metal layers;
wherein, the first circuit and the second circuit form a stacked structure and have electrical connections therebetween, and lower surfaces of the first semiconductor substrate and the second semiconductor substrate respectively serve as an upper surface and a lower surface of the stacked structure.

2. The semiconductor apparatus according to claim 1, wherein, the first semiconductor substrate and the second semiconductor substrate are fabricated based on Wafer-on-Wafer (WoW) technology.

3. The semiconductor apparatus according to claim 1, wherein, one or more sides of a projection region of each circuit block on a lower surface of a corresponding semiconductor substrate are adjacent to or aligned with one or more sides of the lower surface of the corresponding semiconductor substrate.

4. The semiconductor apparatus according to claim 1, wherein, at least two sides of a projection region of at least one circuit block on a lower surface of a corresponding semiconductor substrate are adjacent to or aligned with at least two sides of the lower surface of the corresponding semiconductor substrate.

5. The semiconductor apparatus according to claim 1, wherein, projection regions of two or more different circuit blocks in a same circuit on a lower surface of a corresponding semiconductor substrate have sides of a same length in a first direction.

6. The semiconductor apparatus according to claim 1, wherein, for each circuit block, a projection region of the circuit block on a lower surface of a corresponding semiconductor substrate has a first side longer than a second side, wherein the first side is a side adjacent or parallel to a projection region of another circuit block in the same circuit on the lower surface of the corresponding semiconductor substrate, and the second side is another side of the projection region of the circuit block on the lower surface of the corresponding semiconductor substrate.

7. The semiconductor apparatus according to claim 1, wherein, the first circuit comprises a first circuit block, the second circuit comprises a second circuit block, and the first circuit block and the second circuit block contain a same type of circuit components,
when the first circuit and the second circuit form the stacked structure, the first circuit block and the second circuit block are arranged opposite to each other, or the first circuit block is arranged opposite to another circuit block in the second circuit which is not the second circuit block.

8. The semiconductor apparatus according to claim 1, wherein, one or more metal layers included in one of the first circuit and the second circuit serve as a shared metal layer for supplying a signal/power to a predetermined circuit component included in the other one of the first circuit and the second circuit.

9. The semiconductor apparatus according to claim 1, wherein, the second group of circuit components include one or more voltage regulators, configured to supply power to circuit components to be powered in the first group of circuit components, and
wherein, the one or more voltage regulators are distributed to one or more power supplying circuit blocks of the second circuit, and the one or more power supplying circuit blocks are arranged opposite to circuit blocks to be powered including the circuit components to be powered included in the first circuit.

10. The semiconductor apparatus according to claim 9, wherein, a projection region of the one or more power supplying circuit blocks on the lower surface of the first semiconductor substrate in the first circuit overlaps with a middle region of a projection region of the circuit block to be powered on the lower surface of the first semiconductor substrate.

11. The semiconductor apparatus according to claim 1, wherein, the semiconductor apparatus is a display driver integrated circuit,
the display driver integrated circuit includes circuit components below: a Static Random Access Memory (SRAM), an Auto Place & Route (APR) area, a Gate Driver (GD), a Source Driver (SD), and an Interface (I/O).

12. The semiconductor apparatus according to claim 11, wherein,
the first group of circuit components include the Static Random Access Memory (SRAM) and the Auto Place & Route (APR) area as circuit components to be powered, and the second group of circuit components include the Gate Driver (GD), the Source Driver (SD), and the Interface (I/O),
wherein, the first group of circuit components are distributed to a Static Random Access Memory (SRAM) circuit block and an Auto Place & Route (APR) area circuit block, and the second group of circuit components are distributed to a GD circuit block, an SD circuit block, and an Interface (I/O) circuit block.

13. The semiconductor apparatus according to claim 12, wherein, the first group of circuit components further include another Source Driver (SD) distributed to another SD circuit block in the first circuit,
wherein, the other SD circuit block in the first circuit serves as a first SD circuit block, and the SD circuit block in the second circuit serves as a second SD circuit block, and when the first circuit and the second circuit form the stacked structure, the first SD circuit block and the second SD circuit block are arranged opposite to each other.

14. The semiconductor apparatus according to claim 12, wherein the second group of circuit components further comprises another SRAM distributed to another SRAM circuit block in the second circuit,
wherein, when the first circuit and the second circuit form the stacked structure, the APR circuit block in the first circuit and the other SRAM circuit block in the second circuit are arranged opposite to each other.

15. The semiconductor apparatus according to claim 13, wherein, one or more metal layers, in the first group of metal layers and the second group of metal layers, between the first SD circuit block and the second SD circuit block serve as one or more shared metal layers,
wherein, source drivers included in the first SD circuit block and the second SD circuit block are capable of supplying a signal and/or power to each other through the shared metal layer.

16. The semiconductor apparatus according to claim 12, wherein, one or more metal layers, in the first group of metal layers and the second group of metal layers, between a first circuit block in the first circuit and a second circuit block in the second circuit serve as one or more shared metal layers,
wherein, a first circuit component included in the first circuit block in the first circuit and a second circuit component included in the second circuit block in the second circuit are capable of supplying a signal and/or power to each other through the shared metal layer.

17. The semiconductor apparatus according to claim 12, wherein, the second group of circuit components further include a plurality of voltage regulators,
wherein, the plurality of voltage regulators are arranged in the plurality of power supplying circuit blocks of the second circuit, and the plurality of power supplying circuit blocks are arranged opposite to the SRAM circuit block and the APR circuit block in the first circuit.
